(19) United States
(12) Patent Application Publication
(10) Pub. No.: US 2011/0048489 A1
(43) Pub. Date: Mar. 3, 2011

(54) Combined thermoelectric/photovoltaic device for high heat flux applications and method of making the same

(76) Inventors: Karim M. Gabriel, Lunenburg, MA (US); Mary K. Herndon, Littleton, MA (US); Marcelle S. Ibrahim, Bedford, MA (US)

(21) Appl. No.: 12/802,889

(22) Filed: Jun. 15, 2010

Related U.S. Application Data
(63) Continuation-in-part of application No. 12/584,273, filed on Sep. 1, 2009.

(51) Int. Cl. H01L 35/02; H01L 21/70; H01L 31/18

(52) U.S. Cl. 136/206; 438/54; 438/59; 438/48; 257/E21.532; 257/E31.11

(57) ABSTRACT

A combined thermoelectric/photovoltaic device features a photovoltaic cell with a common electrode, an electrically insulative, thermally conductive layer applied to the common electrode, and an array of thermoelectric couples each including a p-type semiconductor element and an n-type semiconductor element. There is an electrically conductive bridge for each thermoelectric couple formed on the electrically insulative thermally conductive layer. Methods of making such a hybrid device also including a heat sink are also disclosed.

### RELATED APPLICATIONS

This application is a continuation-in-part of U.S. patent application Ser. No. 12/584,273 filed on Sep. 1, 2009.

### FIELD OF THE INVENTION

The subject invention relates to photovoltaic systems, thermoelectric systems, and in particular a hybrid thermoelectric/photovoltaic device.

### BACKGROUND OF THE INVENTION

Photovoltaic (PV) systems convert photons into electricity while thermoelectric (TE) systems convert heat into electricity. Several prior art references propose hybrid photovoltaic/thermoelectric systems.

It is possible, for example, to attach a commercially available photovoltaic cell onto the top of a commercially available thermoelectric module. The interface between the photovoltaic cell and the thermoelectric module, typically an adhesive, solder, or other thermal interface material, however, presents a thermal interface which lowers the efficiency of the system.

U.S. Pat. No. 3,956,017 discloses a solar cell and a heat conduction metal layer made of silver or aluminum provided on the rear surface of the solar cell using vacuum deposition technology. A p-type semiconductor and an n-type semiconductor are soldered to the heat conduction metal layer to form a thermoelectric converter. Lead wires, interconnected via a resistor, are soldered to the p-type semiconductor and the n-type semiconductor to electrically interconnect them. The solar cell converts sunlight into electricity via the optoelectric effect. At the same time, the solar cell is heated and this heat is converted to electricity by the thermoelectric module via the Seebeck effect. Published patent application No. 2006/0225783 also discloses adding thermoelectric material to a photovoltaic cell.

Still, those skilled in the art continue attempts at optimizing hybrid photovoltaic/thermoelectric systems. See for example “Photovoltaic/Thermoelectric Hybrid Systems: A General Optimization Methodology,” Applied Physics Letters 92, 243503 (2008).

One issue in such hybrid systems is that the efficiency of the photovoltaic cell decreases as its temperature increases. Thermoelectric efficiency, on the other hand, increases as temperature differences increase. Cost and manufacturability are also issues.

### BRIEF SUMMARY OF THE INVENTION

In one aspect of the subject invention, a thermoelectric subsystem is added to a photovoltaic cell to both cool and thus increase the efficiency of the photovoltaic cell and also to increase the electrical output of the overall system. One proposed hybrid system is also cost effective to manufacture. The subject invention results from the partial realization, that in one preferred embodiment, an array of thermoelectric couples and a heat sink can be added directly to a commercially available solar cell using a variety of manufacturing techniques not previously employed in fabricating such hybrid systems.

The subject invention, however, in other embodiments, need not achieve all these objectives and the claims hereof should not be limited to structures or methods capable of achieving these objectives.

The subject invention features a combined thermoelectric/photovoltaic device comprising a photovoltaic cell with a common electrode and an electrically insulative, thermally conductive layer applied to the common electrode. The hybrid device includes an array of thermoelectric couples each including a p-type semiconductor element and an n-type semiconductor element. There is an electrically conductive bridge for each thermoelectric couple formed on the electrically insulative thermally conductive layer. A more complete device further includes a cold plate, and a second electrically insulative, thermally conductive layer applied to the cold plate. Electrically conductive bridges electrically connect adjacent thermoelectric couples formed on the second electrically insulative thermally conductive layer. A thermally conductive, low electrically conductive filler such as a ceramic, filled or unfilled polymer, or a sol-gel is disposed between the semiconductor elements.

The cold plate may be solid, or may include passages such as fins for a fluid. Alternatively, of the cold plate can include a porous structure.

In one version, the electrically insulative thermally conductive layers may include aluminum nitride, aluminum oxide, a ceramic material, glass, or a polymeric material. The electrically insulative thermally conductive layers may also include electrodes electrically connected to the bridges.

Typical p-type semiconductors include materials such as Bismuth Telluride and typical n-type semiconductor elements include materials such as Antimony Telluride. There may also be metallization between the thermoelectric couples and their respective bridges.

The subject invention also features a method of making a combined thermoelectric/photovoltaic device. In one example, the method comprises applying (e.g., via deposition) a first electrically insulative thermally conductive layer to the common electrode of a photovoltaic cell, forming an array of electrically conductive bridges on the first electrically insulative thermally conductive layer, and fabricating p-type semiconductor elements and n-type semiconductor elements. A thermoelectric couple is secured to each bridge. Each thermoelectric couple includes a p-type semiconductor element and an n-type semiconductor element. For high temperature applications, spaces between the semiconductor elements and thermoelectric pairs are filled with a thermally conductive compound.

Fabricating the semiconductor elements may include dicing plates of the p-and n-type elements. These p- and n-type plates can be metallized prior to dicing. A pick and place mechanism can be used to secure the couples to the respective bridges. The couples can be soldered or adhered to their respective bridges.

In one example, fabricating the couples and securing them to their respective bridges includes growing the thermoelectric couples on their respective bridges. Printing techniques can be used and the thermoelectric couples may be sintered.

A more complete method further includes applying a second electrically insulative thermally conductive layer to a cold plate and forming an array of electrically conductive bridges on the second electrically insulative thermally conductive layer electrically connecting adjacent thermoelectric couples.

In one example, the p-type and n-type semiconductor elements are first assembled on the electrically conductive bridges of the second electrically insulative thermally conductive layer and they are then secured to their respective bridges formed on the first electrically insulative thermally conductive layer applied to the common electrode of the photovoltaic cell. The electrically conductive bridges can be formed on the first electrically insulative thermally conductive layer and the first electrically insulative thermally conductive layer is then applied to the common electrode. A photovoltaic material is then applied to the common electrode. In some examples, electrodes are formed on the insulative thermally conductive layers.

An exemplary method of manufacturing a hybrid thermoelectric/photovoltaic system includes applying a first electrically insulative thermally conductive layer onto the common electrode of a photovoltaic cell, forming, on the first electrically insulative thermally conductive layer, an array of electrically conductive bridges, and securing one end of a thermoelectric couple to each bridge. A second electrically insulative thermally conductive layer is applied to a cold plate. An array of electrically conductive bridges is formed on the second electrically insulative thermally conductive layer. The opposite ends of the thermoelectric elements of each couple are secured to an electrically conductive bridge on the second electrically insulative thermally conductive layer to electrically connect adjacent thermoelectric couples. Forming the array of electrically conductive bridges on the first electrically insulative thermally conductive layer may include photolithography techniques.

In one example, securing one end of each thermoelectric couple to each bridge on the first electrically insulative thermally conductive layer includes growing the p-type and n-type elements on the bridges of the first electrically insulative thermally conductive layer. The opposite ends of the thermoelectric couples may be secured to an electrically conductive bridge on the second electrically insulative thermally conductive layer by employing a pick and place mechanism.

In another example, securing the opposite ends of the thermoelectric elements of each couple to a bridge on the second electrically insulative thermally conductive layer includes growing the p-type and n-type elements on the bridges of the second electrically insulative thermally conductive layer.

In one example, a combined thermoelectric/photovoltaic device comprises a photovoltaic module and a thermoelectric module coupled to the photovoltaic module. The thermoelectric module includes an array of spaced thermoelectric couples each including a first semiconductor element spaced from a second semiconductor element. A thermally conductive filler is disposed in the spaces between the semiconductor elements and the thermoelectric couples.

There may be an electrically conductive bridge for each thermoelectric couple and an electrically conductive bridge connecting adjacent thermoelectric couples. The photovoltaic module may include a common electrode and the device typically includes an electrically insulative, thermally conductive layer applied to the common electrode. The electrically conductive bridges for each thermoelectric couple can be applied to the electrically insulative, thermally conductive layer.

### BRIEF DESCRIPTION OF THE SEVERAL VIEWS OF THE DRAWINGS

Other objects, features and advantages will occur to those skilled in the art from the following description of a preferred embodiment and the accompanying drawings, in which:

FIG. 1 is a schematic three-dimensional front view showing an example of a hybrid photovoltaic/thermoelectric device in accordance with the prior art;

FIG. 2 is a schematic cross-sectional front view of a combined photovoltaic/thermoelectric device in accordance with one example of the subject invention;

FIG. 3 is a schematic exploded front partial three-dimensional view showing in more detail several of the components of the device of FIG. 2;

FIG. 4 is a schematic cross-sectional front view of the device shown in FIG. 2 depicting the current flow path through the thermoelectric couples in accordance with the subject invention;

FIG. 5 is a flow chart depicting the primary steps associated with one example of manufacturing a hybrid photovoltaic/thermoelectric system in accordance with the subject invention;

FIGS. 6A-6G are highly schematic cross-sectional views showing in more detail the steps associated with one example of making a hybrid system in accordance with the subject invention;

FIGS. 7A-7D are highly schematic cross-sectional front views showing another way to manufacture a hybrid system in accordance with the subject invention;

FIGS. 8A-8H are highly schematic cross-sectional front views showing how a hybrid thermoelectric/photovoltaic system module can be manufactured using ink jet printing and similar methods in accordance with the subject invention; and

FIGS. 9A-9H are highly schematic cross-sectional front views showing still another method of making a hybrid system in accordance with the subject invention.

### DETAILED DESCRIPTION OF THE INVENTION

Aside from the preferred embodiment or embodiments disclosed below, this invention is capable of other embodiments and of being practiced or being carried out in various ways. Thus, it is to be understood that the invention is not limited in its application to the details of construction and the arrangements of components set forth in the following description or illustrated in the drawings. Also, the claims hereof are not to be limited only to the described embodiments. Moreover, the claims hereof are not to be read restrictively unless there is clear and convincing evidence manifesting a certain exclusion, restriction, or disclaimer.

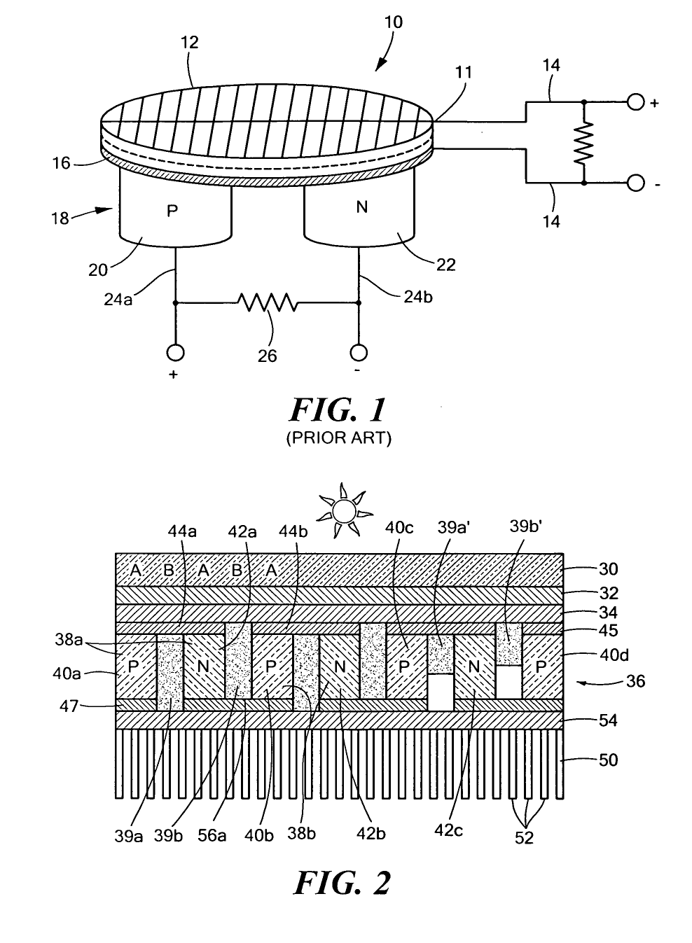

FIG. 1 shows an example of a specially manufactured hybrid thermoelectric/photovoltaic device 10 including solar cell 12 which provides an output voltage via lead wires 14. Added to the back of solar cell 12 using evaporation technology is heat conduction metal layer 16 (e.g., silver or aluminum). Thermoelectric converter 18 includes a p-type semiconductor 20 and an n-type semiconductor 22 both of which are soldered to metal layer 16. Heat generated by solar cell 12 and transferred through metal layer 16 to thermoelectric layer 18 is converted to electricity by semiconductors 20 and 22 producing an electrical output at wires 24a and 24b interconnected via resistor 26.

FIG. 2 shows an example of a combined thermoelectric/photovoltaic device. Photovoltaic cell or module 30 typically has a common (ground) metal electrode 32 on the back side thereof Applied to common electrode 32 is a thin, (e.g., 30 mils) electrically insulating/thermally conductive layer 34. Layer 34 is typically aluminum nitride. Aluminum oxide, ceramic materials, glass, polymeric materials, and/or other thermally conductive/electrically insulative materials can be used. In one example, layer 34 is deposited using a sputtering technique such as DC or RF sputtering. A magnetron sputtering unit may be used to apply a layer of aluminum nitride, (e.g., up to 1.25 microns thick). In other embodiments, this layer is applied using electron beam evaporation, chemical or physical vapor deposition, solution casting, screen printing, ink jet printing, solution plating, or other suitable methods. In the case of casting/printing methods, the material may be dispersed in a binder and removed via thermal methods such as sintering. The material may also be formed without a binder using processes such as slip casting. Layer 34 may also be formed via chemical reactions that form a material using a variety of reaction methods such as addition, condensation, and the like.

The preferred thermoelectric module includes an array 36 of spaced thermoelectric couples. Each couple includes a p-type semiconductor element spaced from an n-type semiconductor element. For example, couple 38a includes p-type semiconductor element 40a and n-type semiconductor element 42a and couple 38b includes p-type semiconductor 40b and n-type semiconductor 42b. The p-type elements may be undoped Bismuth Telluride (Bi₂Te₃) and the n-type elements may be Antimony Telluride (Sb₂Te₃). Other materials may be used.

Electrically conductive bridge 44a formed on electrically insulated thermally conductive layer 34 electrically connects couple 38a and electrically conductive bridge 44b formed on electrically insulated thermally conductive layer 34 electrically connects couple 38b. These bridge elements electrically connect the p-type and n-type semiconductors elements of each couple. Conductive material such as solder, metal electrodes, conductive adhesives and the like may be used. Photolithography techniques may also be used to pattern the bridges on layer 34. Electrode 45 serves to connect p-type element 40d to a common bus as discussed below.

FIG. 2 also shows cold plate 50 with passages such as fins 52 for cooling cold plate 50 via a fluid. Cold plate 50 may be made of any suitable thermally conductive material such as metal, ceramic, and the like. Cold plate may be solid, porous, or have other types of passages such as the fin type embodiment shown in FIG. 2. Another electrically insulative thermally conductive layer 54 (e.g., aluminum nitride) is applied to cold plate 50 using the techniques discussed above with respect to layer 34. Electrically conductive bridges formed on layer 54 electrically connect adjacent thermoelectric couples. For example, bridge 56a electrically connects thermoelectric couple 38a to thermoelectric couple 38b since n-type semiconductor element 42a of thermoelectric couple 38a is electrically connected to p-type element 40b of thermoelectric couple 38b. These bridges may be made of the materials discussed above with respect to bridges 44a and 44b and may be applied to layer 54 using the process discussed above. Electrode 47 electrically connects p-type element 40a to a common bus as described below.

In one example, square plates of n-type material and p-type material are procured and metallized in an e-beam evaporator or using methods previously described. See metallization 43a for element 40a. Chromium (Cr), Gold (Au), Titanium (Ti), and/or Platinum (Pt) materials can be used in addition to other metals. The plates are then diced to produce the individual p-type and n-type elements. The thermoelectric elements may also be produced individually to near net-shape via injection molding or extruded to near net-shape (cross section) and then diced to length. A pick and place machine is used to attach the array of thermoelectric couples to their respective bridges on layer 34. Solder or a conductive adhesive, glass frit, or other suitable material may be used to secure the individual elements to the respective bridges on layers 34 and 54. Cold plate 50 with layer 54 and bridge 56a and the like may be preassembled and then attached to the opposite end of the semiconductor elements.

It was discovered during modeling of the structure shown in FIG. 2 that, particularly for high temperature applications such as solar concentrators, PV module 30 experience undesirable lateral temperature gradients. For example, a temperature difference of over 5° can occur between locations A and B. In one example, location A experienced a temperature of 152.9° C. but location B experienced a temperature of 158.4° C. due to the air gap between semiconductor elements 40a and 42a underneath location B. This temperature difference can cause cracking or warping of PV module 30.

To address these undesirable lateral temperature gradients, thermally conductive filler 39a may be disposed between the semiconductor elements of each thermoelectric couple. Thermally conductive filler 39b may also be disposed between adjacent couples as shown. The filler material or compound may extend between bridge 44a and layer 54 and between bridge 56a and layer 34 or, as shown as 39a′ and 39b′, the spaces between semiconductor elements 40c and 42c and between semiconductor elements 42c and 40d may only be partially filled with the filler material.

Examples of suitable filler compounds include ceramics, filled and unfilled polymers, and sol-gels. The preferred filler is thermally conductive and exhibits a low electrical conductivity. One example is a polymeric material sold under the trade name “OMEGABOND” by Omega Engineering, Inc.

With the filler in place, the lateral temperature gradient in PV module 30 was reduced to less than a degree. For example, location A was at 70.2° C. and location B was at 71.0° C. The thermally conductive filler does affect the performance of the thermoelectric module 36 somewhat but the filler is needed in some high temperature applications to protect the PV module.

Conventional thermoelectric designs and hybrid devices are often gas filled to maximize the thermal gradient through the thickness of the device. High efficiency solar cells, however, require less than a one degree C. lateral thermal gradient. A thick ceramic plate can be used as a heat spreader to address the lateral gradient but a thick ceramic plate is not desirable because it introduces a thermal interface. The filler material of the subject invention addresses the lateral temperature gradient problem and yet does not provide too much of a thermal interface and also provides electrical and environmental insulation.

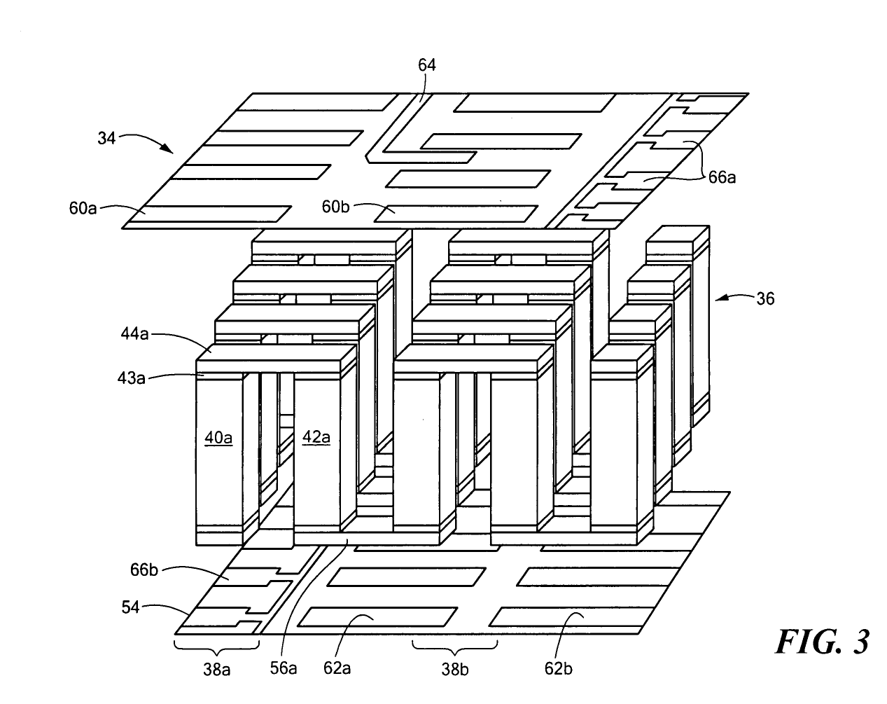

FIG. 3 shows in more detail thermoelectric array 36 as well as the bottom of electrically insulative thermally conductive layer 34 including electrodes 60a, 60b, and the like. Electrode 60a is electrically connected to bridge element 44a of thermoelectric couple 38a and electrode 60b is electrically connected to bridge element 44b of thermoelectric couple 38b. Similarly, electrodes 62a, 62b, and the like are formed on the top of electrically insulative thermally conductive layer 54. These electrodes are electrically connected to the bridge elements between adjacent thermoelectric couples, for example, electrode 62a is electrically connected to bridge element 56a. Electrodes 66a and 66b are also produced in the same way to extract electricity from the thermoelectric array. Typically, layer 34 is also prepared in such a way as to allow the addressing of common lead 64 of the photovoltaic cell. Masking and photolithography techniques can be used to pattern electrode 64 in the top surface of layer 34. As noted above, electrodes 60a and 60b are formed in the bottom surface of layer 34. Again, photolithography techniques can be used to form electrodes 60a, 60b, and the like as well as common bus 66a. The same or similar processes can be used to form the electrodes on the top surface of layer 54. Common busses 66a and 66b are also formed to extract electricity from the thermoelectric array. Note that in some examples, the electrodes in layer 34 may serve as the bridge elements. Thus, electrode 60a could serve as the bridge element for couple 38a. Similarly, if bridge element 44a is present, electrode 60a is not necessarily required.

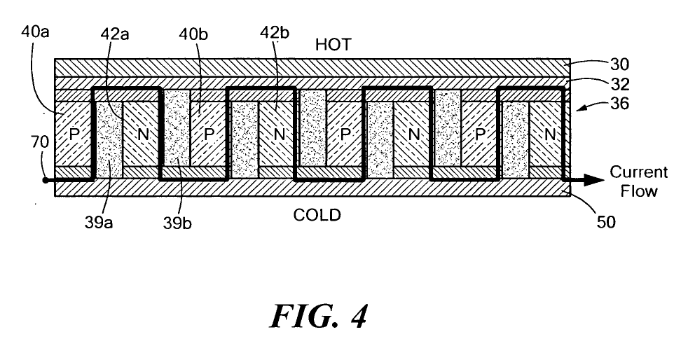

FIG. 4 shows the direction of current flow at 70 for one row of thermoelectric couples in accordance with the configuration discussed above.

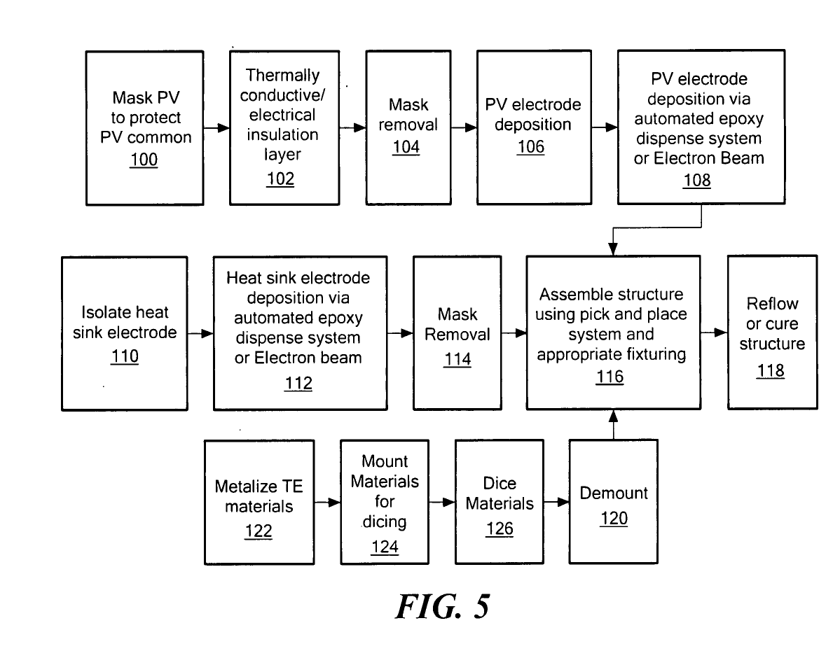

FIG. 5 describes an overview of an exemplary process that can be used to manufacture an improved efficiency hybrid PV/TE module. The process steps can be performed using semiconductor and microelectronic device assembly lines including known production equipment.

In one version, a commercially available PV module (Evergreen Solar 1″×3″ module) is used. The TE module is assembled on the back face of the PV. Prior to processing, the PV module is mounted on a protective surface to shield the PV module during processing. In order to control the flow of charge through the TE, a specific electrode pattern is desired. Typically PV construction utilizes a backside common (ground) electrode which spans the entire back face of the module. This electrode is simultaneously isolated from the TE module and addressable for connecting to adjacent PV modules, step 100.

To provide this insulation, a thin layer of thermally conductive, electrically insulating material is applied via RF sputtering, step 102. The actual thickness may be based on open circuit voltage of PV modules used. The process is conducted using a magnetron sputtering unit. This thin layer provides sufficient electrical isolation while still allowing for adequate conduction of heat from the PV module.

To allow for the addressing of the back face electrode of the PV, photolithography is used to mask a portion of the existing PV electrode, step 100. Prior to the lithography process, the PV module is cleaned and degreased to remove any contaminants that might interfere with subsequent processing. Photoresist is applied to the PV using standard methods and cured. After curing, the back face resist will be exposed on a mask aligner using a mask designed to provide the appropriate electrode patterning. The exposed PV module is immersed in an aqueous solution to develop the exposed resist.

After lithography, the PV module is coated with an insulating layer, via depositions methods previously discussed, such as RF or DC sputtering, step 102. Once the deposition is complete, a solvent based liftoff process may be used to remove the material/resist over the PV module buss bar, step 104. This process may also be used to electrically isolate the cold side substrate of the TE Module, as discussed below.

Electrode patterning for the hot side and cold side of the TE module is performed using an electron beam evaporator. Photolithography is used to mask the surface of the insulating material for the electrode pattern, using a process already described. A different mask, specific to each electrode pattern is designed and used. The front side electrode is made of a conductive material with an appropriate thickness to allow for a reliable electrode that can be soldered or welded, step 108.

In the case of the cold side electrode, the pattern is deposited onto the heat sink material. This material will be cleaned and degreased to remove any contaminants prior to processing. The insulating layer is deposited on this material prior to electrode deposition as previously described, steps 110 and 112.

In order for the TE module to function both p-type and n-type, TE materials are preferred. Undoped Bismuth Telluride (Bi₂Te₃) and Antimony Telluride (Sb₂Te₃) may be used. The material can be purchased in plates and the electrode applied in an ebeam evaporator. After the electrode is applied, step 122, the plates are diced to produce the individual elements.

Once all of the sub-elements have been prepared, the module is assembled using a pick-and place machine. Graphite fixtures are designed and fabricated to ensure proper alignment of the sub-elements during subsequent operations. Graphite combs can be interdigitated between the TE pillars to hold them in place during subsequent processing.

Two methods of fabricating the module are preferred: solder or conductive glass frit attachments and electrically conductive adhesives. Solder attachments provide the ideal thermal and electrical conductivities required but the processing temperatures may not be suitable for all organic PVs. While low temperature solders exist, it is possible that even these temperatures can be too high for some organic PVs.

Solder tabs used for attachments are easily handled by the pick-and-place machine. An automated mix meter system can be used to apply adhesive to the electroded substrates.

Once the module is fully assembled, it is processed to either reflow the solder or cure the adhesive. In the case of the solder, the module is placed in a reflow oven. For adhesive applications, a fixture can be used to apply constant pressure to the module, while it cures in an oven.

Four exemplary methods of fabrication are discussed below including: fabrication of a hybrid module with a commercially available PV as the base, fabrication of a hybrid module with a commercially available PV wherein the TE cold side serves as the base, fabrication of a hybrid module with a polycrystalline PV, formed as part of the process, by starting with the TE cold side, and fabrication of a hybrid module with a polycrystalline PV, formed as part of the process, by starting with the PV.

These methods work for many types of PV materials and TE materials that can be processed by these methods and temperatures. The conductive materials are chosen based on the nature of the PV, i.e., maximum processing temperature, compatibility and chemical resistance.

If required, a thermally conductive filler is also disposed to fill the spaces between the semiconductor elements.

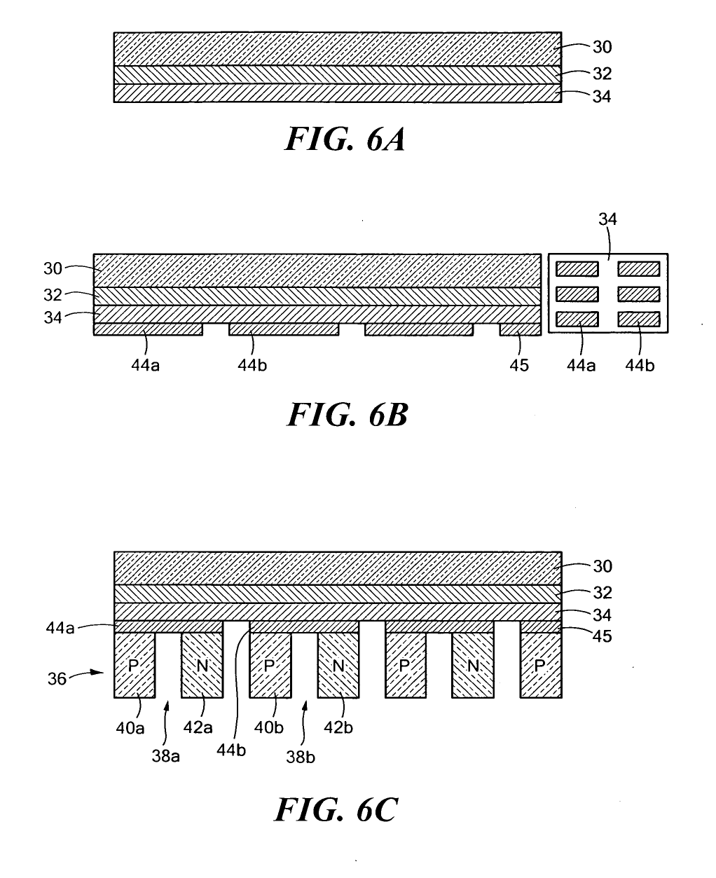

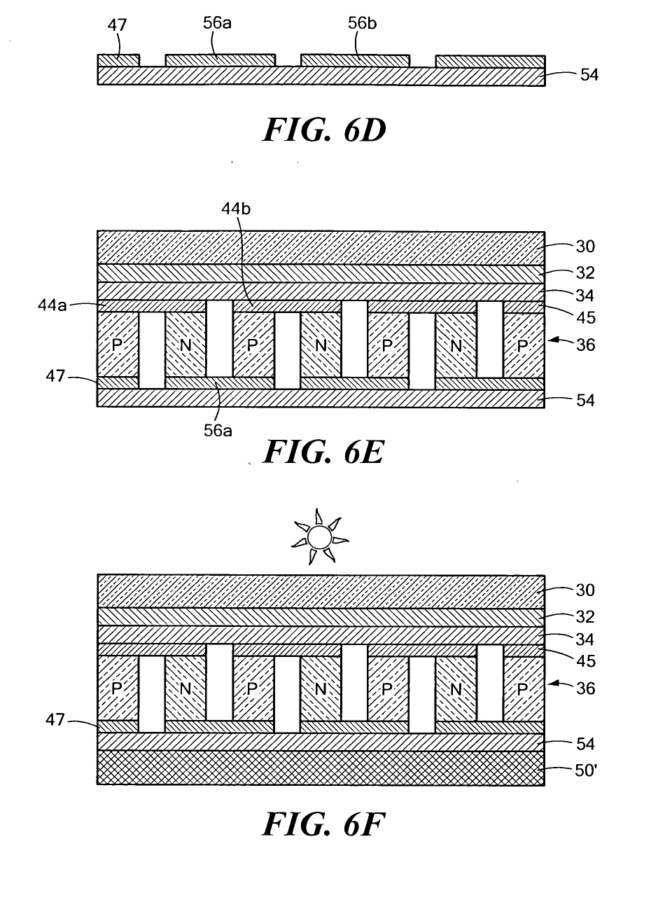

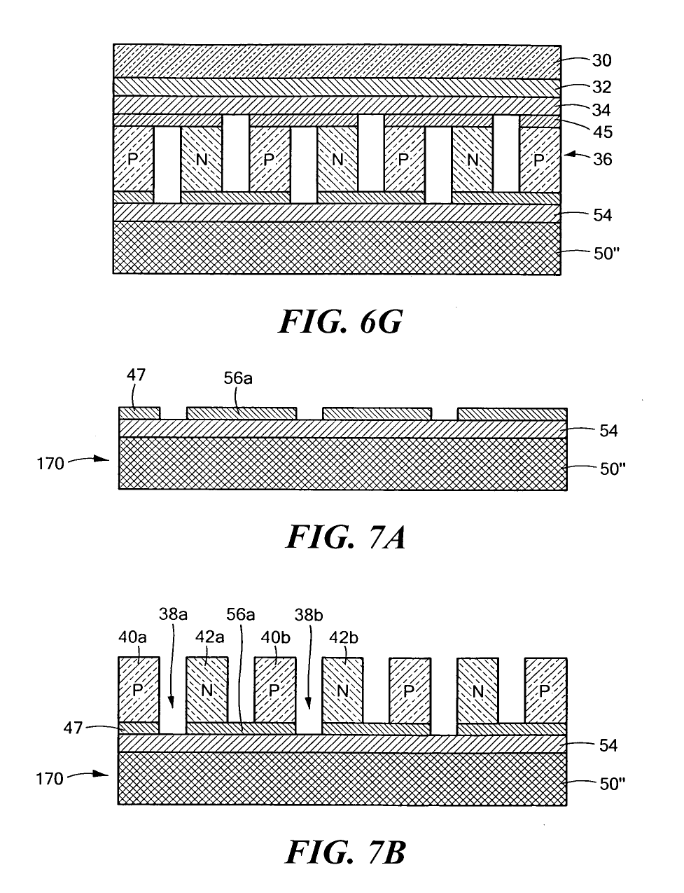

In FIG. 6A, the sun is shown to indicate the hot side (active side) of PV 30. The hot active side would be face down and the materials are applied to the back (common side) of the PV. A protective layer is applied to the PV to prevent damage to the substrate. PV 30 typically includes a common (ground) metal electrode 32 that is continuous along the back side of the PV as shown. To prevent electrical conduction between the thermoelectric element (shorting to ground), electrically insulating thermally conductive layer 34 is applied. This layer can be aluminum nitride, aluminum oxide, or suitable ceramic, glass, polymeric material or any thermally conductive, electrically insulating material. This material can be applied via a variety of deposition methods including DC and RF sputtering, electron beam evaporation, chemical or physical vapor deposition, solution casting, screen printing, ink jet printing, solution plating, or other suitable method. In the case of casting/printing methods the material may be dispersed in a binder and removed via thermal methods such as sintering. The material may also be formed with out a binder using processes such a slip casting. This layer may also be formed via chemical reactions that form the material via a variety of reactions methods such as addition, condensation, etc. As required, the insulation layer may be prepared in such a way as to allow the addressing of the PV common. This may be done via masking and lithography, removing material after processing via ablation, machining, etching, and the like.

Once the isolation layer is applied, modification to the surface to allow for adhesion of solder or other materials may be required. The surface should be modified such that the TE elements are appropriate electrically isolated. The requirement for this step depends on the method of adhesion. Methods such a conductive glass frit, conductive adhesives, etc. may not require this step or may require different materials. Solders may require a metal pad, while adhesive may require a primer such as an organosilane, organometallic, etc. The adhesion layers may be applied using printing methods (ink, screen, etc) or applied via the use of lithographic methods, where a pattern is created and the materials applied. Application methods include PVD, CVD, sputtering, E-beam deposition, electro plating, chemical reactions, etc (including methods previously discussed).

Once the insulation layer has been deposited and the surface prepared for adhesion, thermoelectric elements 40a, 42a, FIG. 6C and the like are applied. These elements can be applied via use of pick and place equipment or other suitable in instances where the elements are large enough to be used by these processes. The TE materials can be fully sintered (polycrystalline), single crystal, or a green body (requiring densification). Strips of p- and n-type materials may be attached and then sub-diced, etched, ion milling, or ablated to create this structure, i.e., controlled removal in a prescribed pattern. Semiconductor materials may be applied in bulk, sub-diced or separated as previously discussed and doped via diffusion processing to create suitable materials. As required, metallization may be applied to the TE material to increase adhesion.

An alternate method is to grow the elements. In one example, a TE powder/binder or powder only is applied directly to the PV using techniques such as ink jet printing, screen printing, stereo lithography, and the like. The structure created is a three dimensional interdigitated structure where the current flows from p-type material to n-type material producing electricity. If needed, a thermally conductive filler material is also disposed between the semiconductor elements using these same techniques.

The cold side plate is then prepared using the methods previously discussed. An AlN or similar material plate 54, FIG. 6D, as discussed (electrically insulating, thermally conductive) is treated to allow for adhesion to the TE elements. Electrical connections, or bridges, (56a, 56b, and 47 of FIG. 6d) should be applied via methods previously discussed to complete the electrical circuit, as shown in FIG. 4. To complete the module, FIG. 6E, the cold side is mated to the hot side, using fixtures to position the elements. These fixtures align the elements and hold them in position during processing. These fixtures may be “lost castings” or reusable depending on the nature of the process. The module is processed based on the adhesion layers and TE material. This process can include sintering, reflow solder, curing of adhesives, etc. Sintering includes pressureless sintering, hot and cold isostatic pressing methods, vacuum sintering, etc. Once completed a heat conduction layer 50′, FIG. 6F is applied to insulation layer 54 to conduct heat from the cold side. This may be attached or fabricated via a variety of methods including bonding/soldering of the layer (solid, fins, porous). Alternately, the metal layer can be applied via powder metallurgy techniques and sintered to create the heat conduction layer. This layer may be solid, fin shaped or porous as shown for layer 50″, FIG. 6G. In the case of the porous media, a fluid can be passed through it. In the other cases, the fluid is passed over the heat sink to conduct the heat away to create the thermal gradient required for operation. Heat fins can also be applied to conduct the heat way, either by direct bonding, or powder metallurgical methods as previously described. If required, a filler material can also be added after the structure is completed.

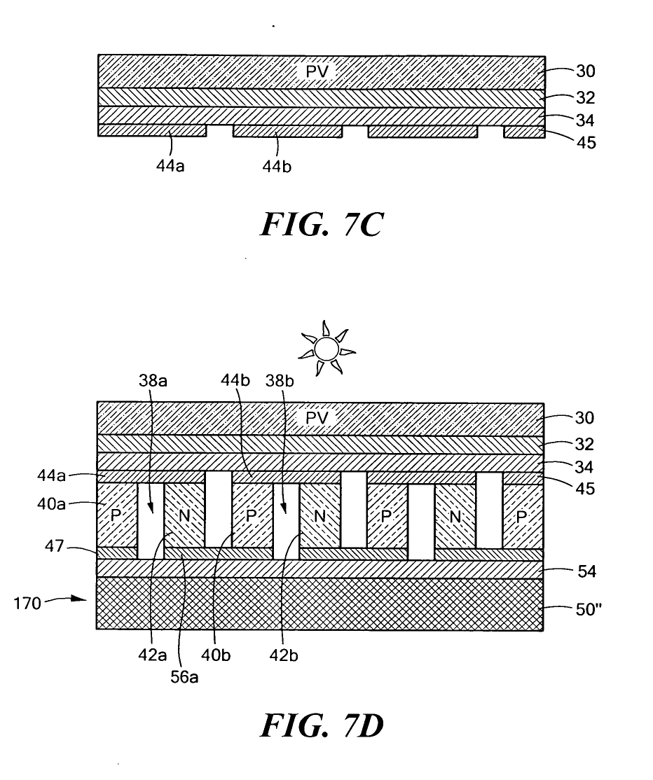

The above structure can also be made using the techniques similar to those discussed above and as illustrated in FIG. 7A-7D. Again the sun is shown to indicate the hot side (active side) of the PV. In the first few steps, the PV would not be present. First, cold side 170, FIG. 7A is created. The TE materials are then applied as shown in FIG. 7B. The PV submodule is then prepared, FIG. 7C. The PV submodule is then applied to the structure and the hybrid device is finished by reflow, sinter or curing the structure, FIG. 7D. Sintering may include pressureless sintering, hot and cold isostatic pressing methods, vacuum sintering, and the like.

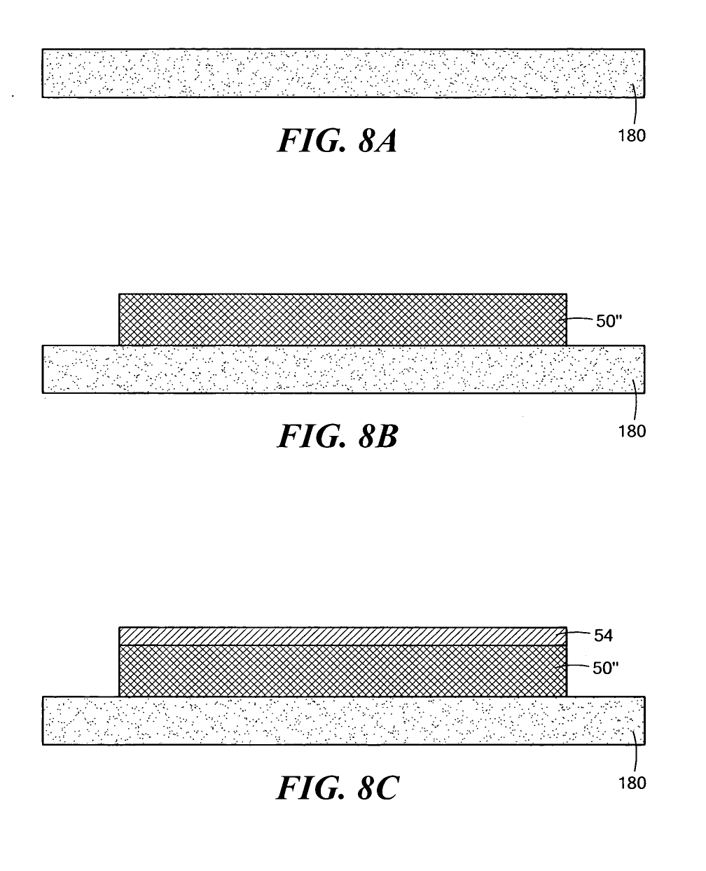

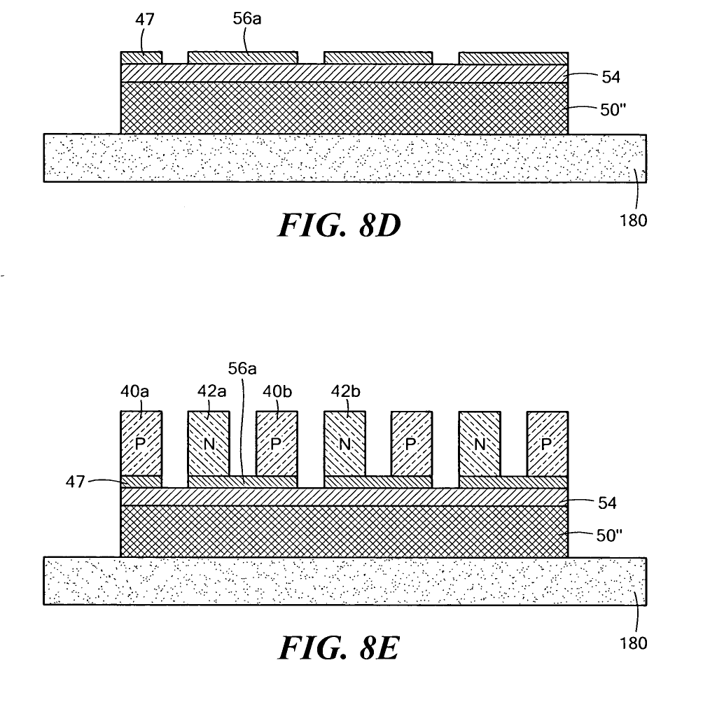

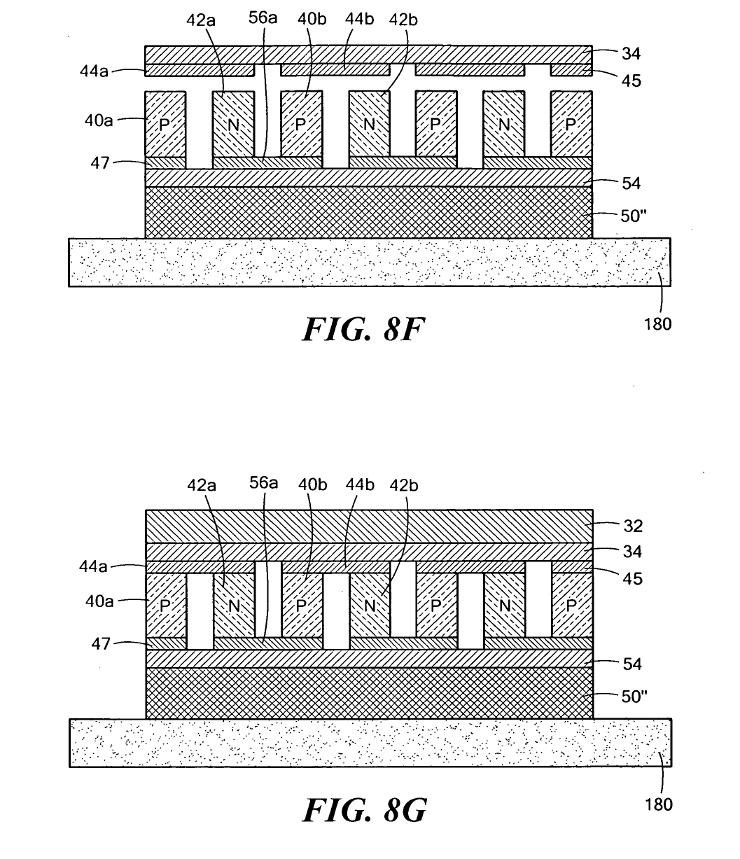

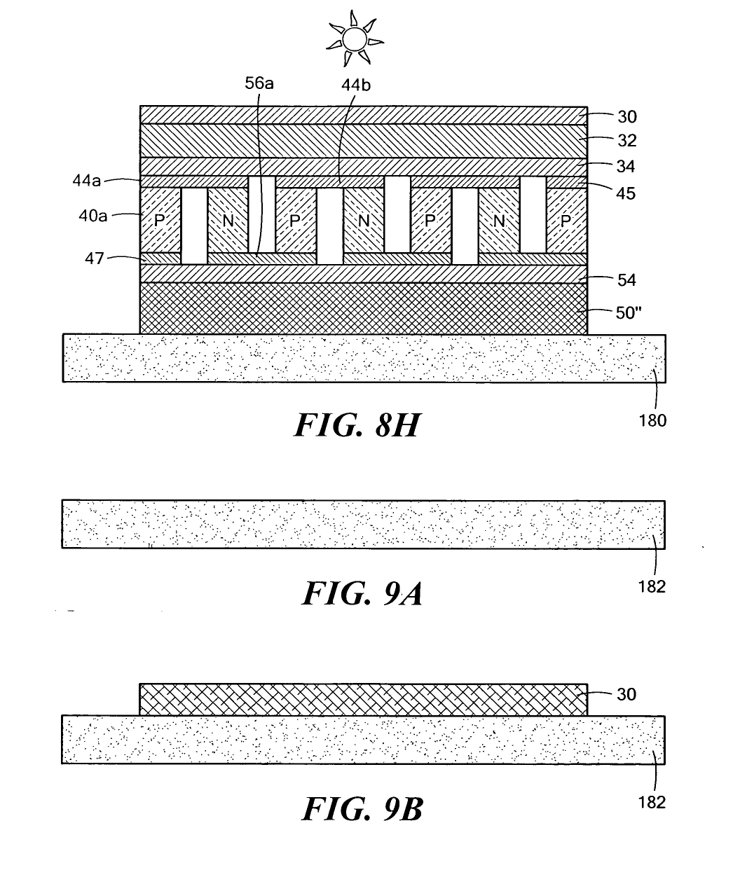

Fabrication of a hybrid module from ink jet printing or similar methods is also possible. The following steps can be done in either order, i.e., PV first or TE first. The TE first process, FIGS. 8A-8H, is shown with the “sun” on top to indicate direction of PV (last layer). Antireflection coatings and electrodes can be applied after burnout/sintering or as part of the process. This method will produce an inorganic polycrystalline process as follows. Continuous film, fin or porous structures can be made this way (porous structure shown for simplicity). The entire structure is confirmed to create the module. First, a porous release layer/setter 180, FIG. 8A such as zirconia, alumina, or other non reactive temperature resistant material is prepared for use. This may include cleaning, burn out, and a layer of a powder such as graphite, silicon, etc applied to facilitate processing, release, and or doping of the substrate. Next, a thermally conductive layer 50″, FIG. 8B made of either metal or ceramic is deposited on the surface of setter 180. The material is capable of surviving the sintering temperature of the various materials. A thermally insulating layer 54, FIG. 8C is then deposited in the case of solid and porous structures. In the case of fin structures, a solid thin plate of ceramic may be applied. This method can also be used for the other two structures as well.

The tie layers, (e.g., bridge 56a and electrode 47, FIG. 8D) are deposited onto this layer or, in the case of the plate, this layer can be applied in a separate step. The layer is made of material that can survive the sintering process such as conductive glass frit, conductive ceramic, high temperature metals. The TE elements are then applied as shown in FIG. 8E either by inkjet processes or pick and place processing. The material may also be formed using the other methods previously described.

Electrically insulating layer 34, FIG. 8F is applied in plate form. The plate has the tie layers already applied, as required, in the event that a bridging structure for the electrode/tie layer can not be made with a deposition method. The tie layers can also be applied directly to the TE elements. See bridges 44a and 44b and electrode 45. PV common electrode 32, FIG. 8G is then applied either to plate 34 either during or before assembly. PV material 30, FIG. 8H is applied. This material can be either pure or regrind. The top side electrode and antireflection layers can be applied prior to sintering or after depending on the nature of the material and sintering temperatures.

The resulting module is then sintered. Sintering includes pressureless sintering, hot and cold isostatic pressing methods, vacuum sintering, and the like.

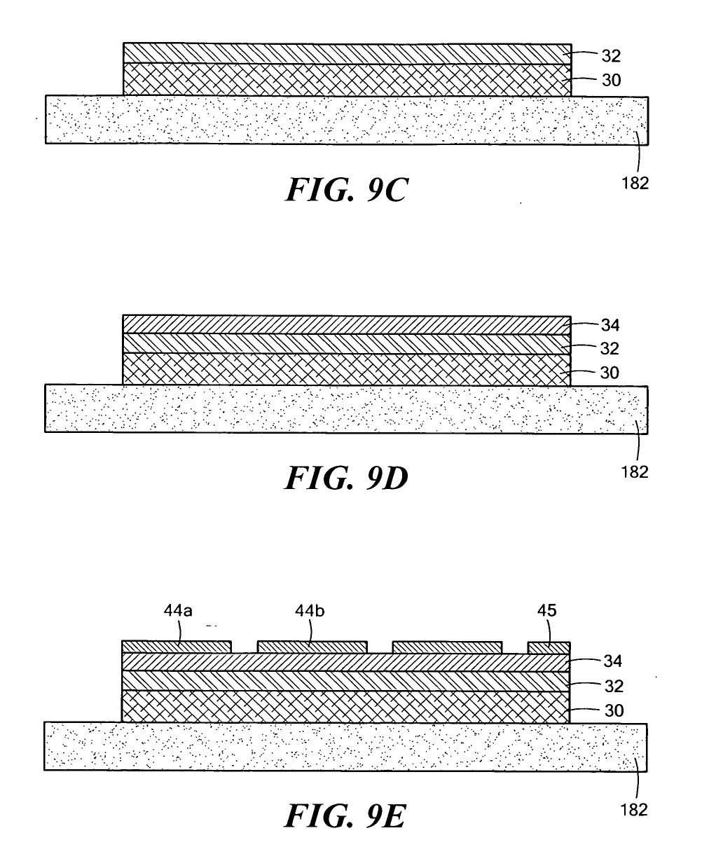

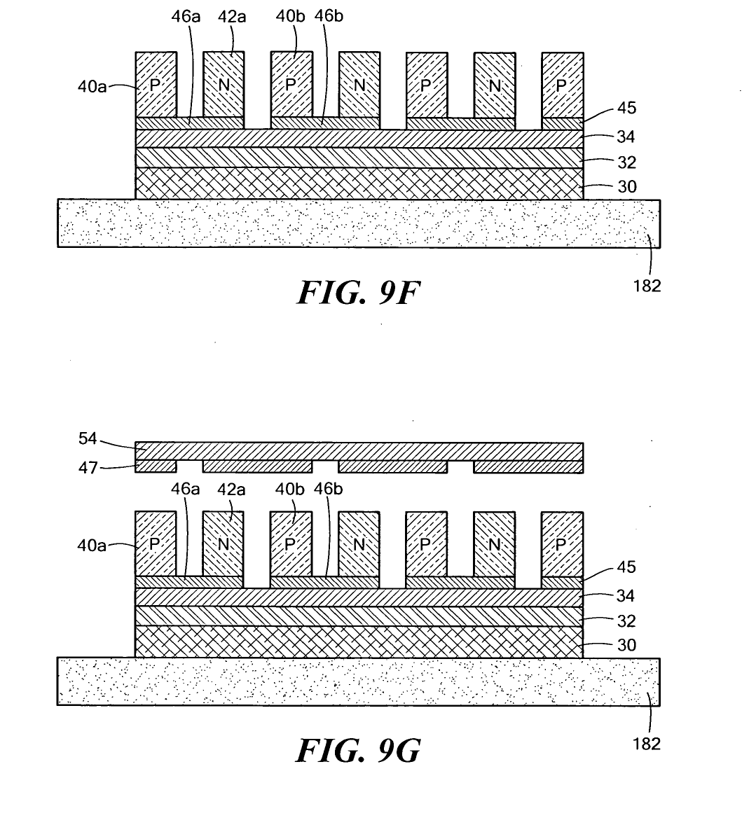

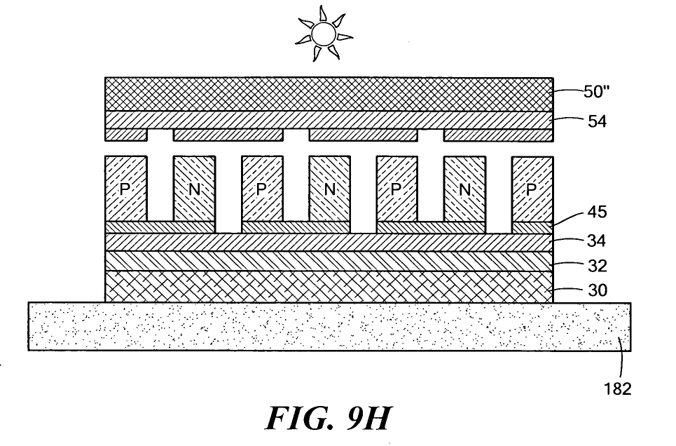

In a reverse method, all the steps are the same, except that the hot side electrode and antireflective coating may be applied after sintering if the process used does not allow for bridging of material. These steps are shown in FIGS. 9A-9H. In this instance, the PV hot side would be in contact with the setter.

Setter layer 182, FIG. 9A is prepared and the PV material 30, FIG. 9B is applied. Common electrode 32, FIG. 9C is applied and then the insulative material 34 is applied, FIG. 9D. The conduction paths and adhesion layers are then applied as shown in FIG. 9E. The TE couples are then applied as shown in FIG. 9F. Insulation material 54 is then prepared, FIG. 9G and applied and the cold side (a porous structure 50″, FIG. 9H is shown, but any of the structures are possible) and the module is sintered, as previously discussed.

In FIGS. 7, 8, and 9, a thermally conductive filler can be added if needed during fabrication of the device or after it is fully assembled as shown in FIG. 2.

The result in one preferred embodiment is an integrated system where a thermoelectric array and a heat sink are added to a photovoltaic cell to both cool and thus increase the efficiency of the photovoltaic cell and also to increase the electrical output of the overall system. Cost effective techniques are preferably used to mass manufacture hybrid systems in accordance with the subject invention. In higher temperature applications, the thermally conductive filler in the spaces between the semiconductor elements prevents damage to the photovoltaic cell.

Although specific features of the invention are shown in some drawings and not in others, however, this is for convenience only as each feature may be combined with any or all of the other features in accordance with the invention. The words “including”, “comprising”, “having”, and “with” as used herein are to be interpreted broadly and comprehensively and are not limited to any physical interconnection. Moreover, any embodiments disclosed in the subject application are not to be taken as the only possible embodiments.

In addition, any amendment presented during the prosecution of the patent application for this patent is not a disclaimer of any claim element presented in the application as filed: those skilled in the art cannot reasonably be expected to draft a claim that would literally encompass all possible equivalents, many equivalents will be unforeseeable at the time of the amendment and are beyond a fair interpretation of what is to be surrendered (if anything), the rationale underlying the amendment may bear no more than a tangential relation to many equivalents, and/or there are many other reasons the applicant can not be expected to describe certain insubstantial substitutes for any claim element amended.

Other embodiments will occur to those skilled in the art and are within the following claims.

What is claimed is:

1. A combined thermoelectric/photovoltaic device comprising:
a photovoltaic cell with a common electrode;
an electrically insulative, thermally conductive layer applied to the common electrode;
an array of spaced thermoelectric couples each including a p-type semiconductor element spaced from an n-type semiconductor element;
an electrically conductive bridge for each thermoelectric couple formed on the electrically insulative, thermally conductive layer; and
a thermally conductive, low electrically conductive filler in spaces between the semiconductor elements and the thermoelectric couples.

2. The device of claim 1 further including:
a cold plate;
a second electrically insulative, thermally conductive layer applied to the cold plate;
electrically conductive bridges electrically connecting adjacent thermoelectric couples formed on the second electrically insulative, thermally conductive layer;
the filler disposed between the first and second electrically insulative, thermally conductive layers.

3. The device of claim 1 in which the electrically insulative, thermally conductive layer includes aluminum nitride.

4. The device of claim 1 in which the electrically insulative, thermally conductive layer includes aluminum oxide.

5. The device of claim 1 in which the electrically insulative, thermally conductive layer includes a ceramic material.

6. The device of claim 1 in which the electrically insulative, thermally conductive layer includes glass.

7. The device of claim 1 in which the electrically insulative, thermally conductive layer includes a polymeric material.

8. The device of claim 1 in which the electrically insulative, thermally conductive layer includes electrodes electrically connected to the bridges.

9. The device of claim 1 in which the p-type semiconductors include Bismuth Telluride.

10. The device of claim 1 in which the n-type semiconductor elements include Antimony Telluride.

11. The device of claim 1 further including metallization between the thermoelectric couples and their respective bridges.

12. The device of claim 1 in which the filler includes ceramic, filled or unfilled polymer, or sol-gel compounds.

13. A method of making a combined thermoelectric/photovoltaic device, the method comprising:
applying a first electrically insulative, thermally conductive layer to the common electrode of a photovoltaic cell;
forming an array of spaced electrically conductive bridges on the first electrically insulative, thermally conductive layer;
fabricating p-type semiconductor elements and n-type semiconductor elements;
securing a thermoelectric couple to each bridge, each thermoelectric couple including a p-type semiconductor element spaced from an n-type semiconductor element; and
filling spaces between the thermoelectric couples and semiconductor elements with a thermally conductive, low electrically conductive filler.

14. The method of claim 13 in which fabricating includes dicing plates of the p- and n-type elements.

15. The method of claim 13 in which p- and n-type plate are metallized prior to dicing.

16. The method of claim 13 in which securing includes employing a pick and place mechanism.

17. The method of claim 13 in which securing includes soldering or adhering the thermoelectric couples to their respective bridges.

18. The method of claim 13 in which fabricating and securing includes growing said thermoelectric couples on their respective bridges.

19. The method of claim 18 in which growing includes printing.

20. The method of claim 18 further including the step of sintering the thermoelectric couples.

21. The method of claim 13 further including applying a second electrically insulative, thermally conductive layer to a cold plate; and
forming an array of electrically conductive bridges on the second electrically insulative thermally conductive layer electrically connecting adjacent thermoelectric couples.

22. The method of claim 21 in which the p-type and n-type semiconductor elements are first assembled on to the electrically conductive bridges of the second electrically insulative thermally conductive layer and then secured to their respective bridges formed on the first electrically insulative thermally conductive layer applied to the common electrode of the photovoltaic cell.

23. The method of claim 22 in which the electrically conductive bridges are formed on the first electrically insulative thermally conductive layer and the first electrically insulative thermally conductive layer is then applied to the common electrode.

24. The method of claim 23 further including applying photovoltaic material to the common electrode.

25. The method of claim 13 in which the first electrically insulative thermally conductive layer is deposited on the common electrode.

26. The method of claim 13 further including the step of forming electrodes on the first electrically insulative thermally conductive layer.

27. The method of claim 13 in which the filler includes ceramic, filled or unfilled polymer, or sol-gel compounds.

28. A combined thermoelectric/photovoltaic device comprising;
a photovoltaic module; and
a thermoelectric module coupled to the photovoltaic module, the thermoelectric module including an array of spaced thermoelectric couples each including a first semiconductor element spaced from a second semiconductor element, and
a thermally conductive filler in spaces between the semiconductor elements and the thermoelectric couples.

29. The device of claim 28 in which the filler includes ceramic, filled or unfilled polymer, or sol-gel compounds.

30. The device of claim 28 further including an electrically conductive bridge for each thermoelectric couple and an electrically conductive bridge connecting adjacent thermoelectric couples.

31. The device of claim 30 in which the photovoltaic module includes a common electrode and the device further includes an electrically insulative thermally conductive layer applied to the common electrode, the electrically conductive bridges for each thermoelectric couple applied to the electrically insulative, thermally conductive layer.
